(19) United States
(12) Patent Application Publication
(10) Pub. No.: US 2016/0013158 A1
(43) Pub. Date: Jan. 14, 2016

(54) SEMICONDUCTOR PACKAGE

(71) Applicants: Hyo-Soon KANG, Seoul (KR); SunWon KANG, Seongnam-si (KR)

(72) Inventors: Hyo-Soon KANG, Seoul (KR); SunWon KANG, Seongnam-si (KR)

(21) Appl. No.: 14/718,313

(22) Filed: May 21, 2015

(30) Foreign Application Priority Data
Jul. 8, 2014 (KR) 10-2014-0085338

(51) Int. Cl. H01L 25/065; H01L 23/498; H01L 23/31

(52) U.S. Cl. CPC H01L 25/0657; H01L 23/3157; H01L 23/49811; H01L 23/49827; H01L 23/49838; H01L 2225/0651; H01L 2225/0652

(57) ABSTRACT

A semiconductor package is provided. The semiconductor package includes a package substrate, a semiconductor chip, bonding wires, and a molding film. The package substrate includes a first surface having a recessed portion, a second surface opposed to the first surface, an opening extending from the recessed portion of the first surface to the second surface, and bonding pads provided on the first surface. The semiconductor chip is disposed on the second surface of the package substrate to cover the opening, and includes center pads exposed through the opening. Bonding wires electrically connect the center pads and the bonding pads through the opening. The molding film covers the bonding pads, the center pads, and the bonding wires. A depth of the recessed portion is greater than a distance between the recessed portion of the first surface and a lowermost surface of the molding film.

### CROSS-REFERENCE TO RELATED APPLICATIONS

This patent application claims priority from Korean Patent Application No. 10-2014-0085338, filed on Jul. 8, 2014, the entire contents of which are hereby incorporated by reference.

### BACKGROUND

1. Field

The present disclosure relates to a semiconductor device, and more particularly, to a semiconductor package.

2. Description of Related Art

With the development of the electronics industry, demands for high functionality, high-speed response and miniaturization of electronic components increase. In response to such a trend, semiconductor packaging methods in which a plurality of semiconductor chips are stacked on a single printed circuit board, or a package is stacked on a package are on the rise. In particular, a package-on-package technology in which a package is stacked on a package may reduce a mounting area and a connection path between two packages. Therefore, the package-on-package technology is widely used in mobile devices such as smartphones and the like, and it is expected to increase the use of the package-on-package technology in subminiature products, such as wearable devices and the like.

### SUMMARY

One or more exemplary embodiments provide a semiconductor package with a reduced manufacturing cost.

One or more exemplary embodiments also provide a semiconductor package with increased miniaturization.

According to an aspect of an exemplary embodiment, there is provided a semiconductor package including a package substrate, a semiconductor chip, bonding wires, and a molding film. The package substrate includes a first surface having a recessed portion, a second surface opposed to the first surface, an opening extending from the recessed portion of the first surface to the second surface, and bonding pads provided on the first surface. The semiconductor chip is disposed on the second surface of the package substrate to cover the opening, and includes center pads exposed through the opening. The bonding wires electrically connect the center pads and the bonding pads through the opening. The molding film covers the bonding pads, the center pads, and the bonding wires. A depth of the recessed portion is greater than a distance between the recessed portion of the first surface and a lowermost surface of the molding film.

According to an aspect of another exemplary embodiment, there is provided a stack type semiconductor package including an upper package substrate, an upper semiconductor chip, bonding wires, a molding film, a lower package substrate, a lower semiconductor chip, and connection members. The upper package substrate includes a first surface having a recessed portion, a second surface opposed to the first surface, an opening extending from the recessed portion of the first surface to the second surface, bonding pads provided on the first surface, and upper connection pads provided on the first surface. The upper semiconductor chip is disposed on the second surface of the upper package substrate to cover the opening, and includes center pads exposed through the opening. The bonding wires electrically connect the center pads and the bonding pads through the opening. The molding film covers the bonding pads, the center pads, and the bonding wires. The lower package substrate is disposed under the upper package substrate, and includes an upper surface and lower connection pads provided on the upper surface. The lower semiconductor chip is disposed between the upper package substrate and the lower package substrate, and is electrically connected to the lower package substrate. The connection members electrically connect the upper connection pads and the lower connection pads. At least a portion of the lower semiconductor chip is inserted into the recessed portion.

According to an aspect of another exemplary embodiment, there is provided a stack type semiconductor package including a first substrate, a first semiconductor chip, bonding wires, a molding film, a second substrate, and a second semiconductor chip. The first substrate includes bonding pads, a recessed portion, and an opening formed in the recessed portion. The first semiconductor chip is disposed on the first substrate, and covers the opening. The first semiconductor chip includes center pads exposed through the opening. The bonding wires extend through the opening, and connect the center pads of the first semiconductor chip and the bonding pads of the first substrate. The molding film is disposed on a surface of the first substrate opposite from the first semiconductor chip, and covers the opening, the bonding pads, the center pads, and the bonding wires. The second semiconductor chip is disposed on the second substrate and disposed between the first substrate and the second substrate. At least a portion of the second semiconductor chip is inserted into the recessed portion of the first substrate.

### BRIEF DESCRIPTION OF THE DRAWINGS

The above and other aspects will be clearly understood to those skilled in the art from the following description and the accompanying drawings. The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a plane view of semiconductor packages according to first to third exemplary embodiments;

FIGS. 2 to 4 are cross-section views of semiconductor packages according to the first to third exemplary embodiments, respectively, taken along a line I-I′ of FIG. 1;

FIG. 5 is a plane view of a semiconductor package according to a fourth exemplary embodiment.

FIG. 6 is a cross-sectional view of a semiconductor package taken along a line II-II′ of FIG. 5;

FIG. 7 is a plane view of a semiconductor package according to a fifth exemplary embodiment;

FIG. 8 is a cross-sectional view of a semiconductor package taken along a line III-III′ of FIG. 7;

FIG. 9 is a plane view of a stack type semiconductor package according to an exemplary embodiment;

FIG. 10 is a cross-sectional view taken along line IV-IV′ of FIG. 9;

FIG. 11 is a plane view of a stack type semiconductor package according to another exemplary embodiment;

FIG. 12 is a cross-sectional view taken along line V-V′ of FIG. 11;

FIG. 13 is a view illustrating an electronic device to which a semiconductor package according to an exemplary embodiment is applied; and

FIG. 14 is a block diagram schematically illustrating an electronic device to which a semiconductor package according to an exemplary embodiment is applied.

### DETAILED DESCRIPTION OF EXEMPLARY EMBODIMENTS

Aspects of the present inventive concept and methods of accomplishing the same may be understood more readily with reference to the following detailed description of exemplary embodiments and the accompanying drawings. The inventive concept may, however, be embodied in many different forms and should not be construed as being limited to the exemplary embodiments set forth herein; rather, these exemplary embodiments are provided so that this disclosure will be thorough and complete, and will fully convey the concept of the inventive concept to those skilled in the art. Further, the present inventive concept is only defined by the scopes of the claims. Like reference numerals refer to like elements throughout.

In the following description, the technical terms are used only for explaining exemplary embodiments while not limiting the present inventive concept. The terms of a singular form may include plural forms unless otherwise specified. Also, the meaning of “include,” “comprise,” “including,” or “comprising,” specifies a property, a region, a fixed number, a step, a process, an element and/or a component but does not exclude other properties, regions, fixed numbers, steps, processes, elements and/or components.

Additionally, exemplary embodiments in the detailed description will be described with sectional views as ideal exemplary views. In the figures, the dimensions of layers and regions are exaggerated for clarity of illustration. Accordingly, shapes of the exemplary views may be modified according to manufacturing techniques and/or allowable errors. Therefore, the exemplary embodiments are not limited to the specific shape illustrated in the exemplary views, but may include other shapes that may be created according to manufacturing processes. For example, an etched region illustrated as a rectangle may have rounded or curved features. Areas exemplified in the drawings have general properties, and are used to illustrate a specific shape of a semiconductor package region. Thus, this should not be constructed as limited to the scope of the present inventive concept.

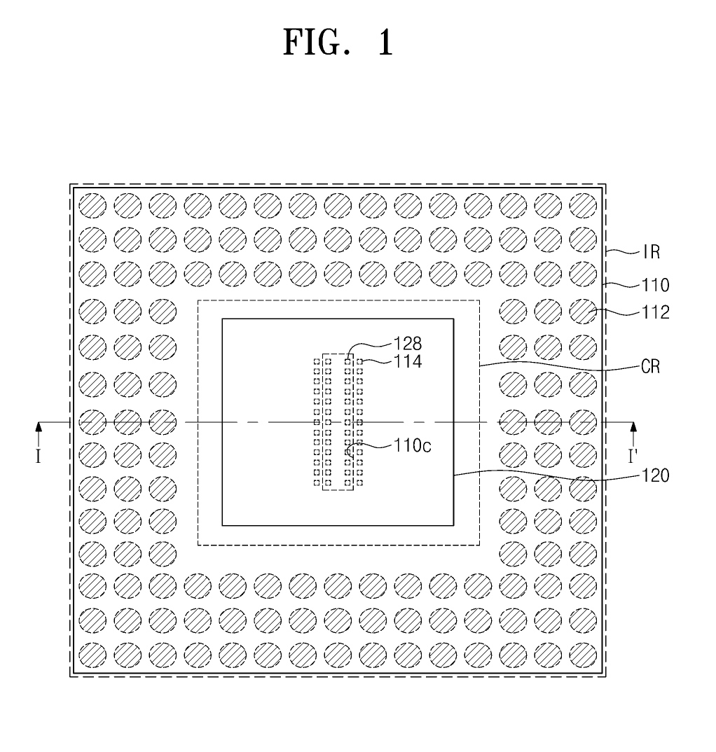

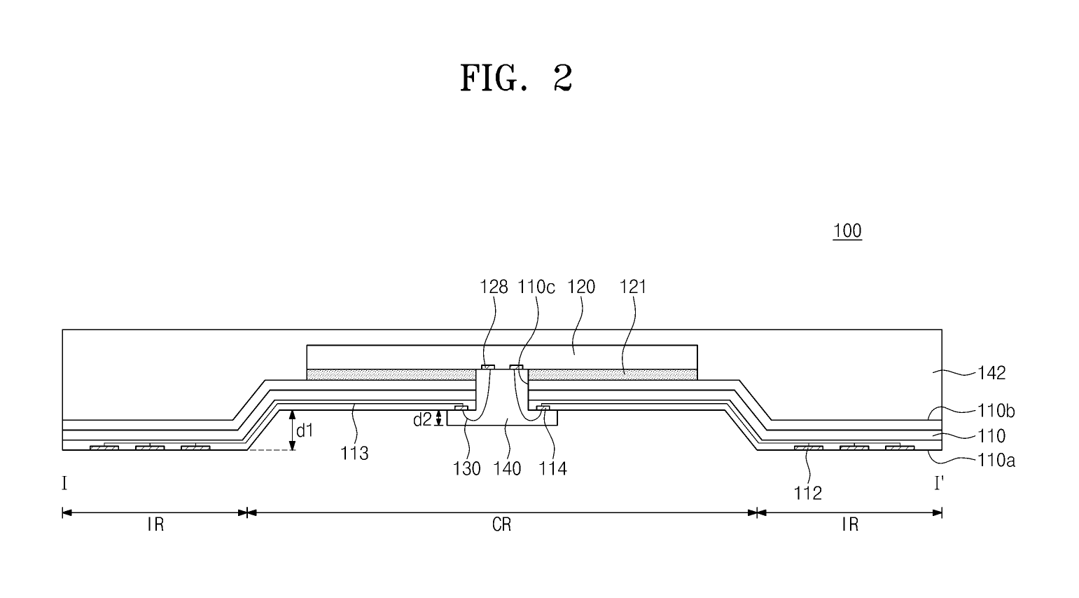

FIG. 1 is a plane view of semiconductor packages according to first, second, and third exemplary embodiments. FIG. 2 is a cross-sectional view taken along line I-I′ of FIG. 1. Hereinafter, a semiconductor package according to a first exemplary embodiment will be described with reference to FIGS. 1 and 2.

Referring to FIGS. 1 and 2, a semiconductor package 100 may include a package substrate 110, a first semiconductor chip 120, first bonding wires 130, a first molding film 140, and a second molding film 142.

The package substrate 110 may have a first surface 110a, and a second surface 110b opposed to the first surface 110a, and may include a chip region CR at a center thereof and an interconnection region IR around the chip region CR. The first surface 110a of the package substrate 110 may have a recessed portion in the chip region CR and the second surface 110b of the package substrate 110 may have a protruding portion in the chip region CR, the protruding portion corresponding to the recessed portion. Also, the package substrate 110 may have an opening 110c formed in the chip region CR and extending from the first surface 110a to the second surface 110b. The package substrate 110 may include connection pads 112 and first bonding pads 114. The connection pads 112 may be disposed on the first surface 110a in the interconnection region IR and the first bonding pads 114 may be disposed adjacent to the opening 110c on the first surface 110a in the chip region CR. The connection pads 112 and the first bonding pads 114 may be electrically connected to each other through an inner interconnection layer 113. The connection pads 112, the first bonding pads 114 and the inner interconnection layer 113 may be formed on the same layer. According to an exemplary embodiment, the package substrate 110 may include a plurality of stacked insulation layers, and the connection pads 112, the first bonding pads 114 and the inner interconnection layer 113 may be disposed between the stacked insulation layers. The connection pads 112 and the first bonding pads 114 may be exposed by an opening formed on the insulation layer. For example, the package substrate 110 may be a printed circuit board or a flexible printed circuit board.

The first semiconductor chip 120 may be disposed on the second surface 110b of the package substrate 110 so as to cover the opening 110c. In case that the second surface 110b of the package substrate 110 has the protruding portion, the first semiconductor chip 120 may be disposed on the protruding portion of the second surface 110b. The first semiconductor chip 120 may be attached to the second surface 110b of the package substrate 110 using an adhesive film 121. The first semiconductor chip 120 may include center pads 128. The center pads 128 may be disposed on a lower surface of the first semiconductor chip 120 exposed through the opening 110c of the package substrate 110. The first semiconductor chip 120 may be, for example, a memory device, such as, for example, a DRAM, NAND flash, NOR flash, OneNAND, PRAM or MRAM, or the like.

The first bonding wires 130 may be provided to penetrate the opening 110c. The first bonding wires 130 may electrically connect the first bonding pads 114 of the package substrate 110 and the center pads 128 of the first semiconductor chip 120.

The first molding film 140 may be formed so as to cover the first bonding pads 114, the center pads 128 and the first bonding wires 130. The first molding film 140 may fill the opening 110c of the package substrate 110. A recessed depth d1 of the recessed portion of the first surface 110a may be greater than a distance d2 between the recessed portion of the first surface 110a and a lowermost surface of the first molding film 140. In other words, the distance d2 between the first surface 110a in the chip region CR of the package substrate 110 and the lowermost surface of the molding film 140 may be less than the height difference d1 between the interconnection region IR and the chip region CR of the package substrate 110.

The second molding film 142 may be formed so as to cover the first semiconductor chip 120 and the second surface 110b of the package substrate 110. The second molding film 142 may cover the semiconductor chip 120 and all or a portion of the second surface 110b. The first and second molding films 140 and 142 may include an epoxy molding compound.

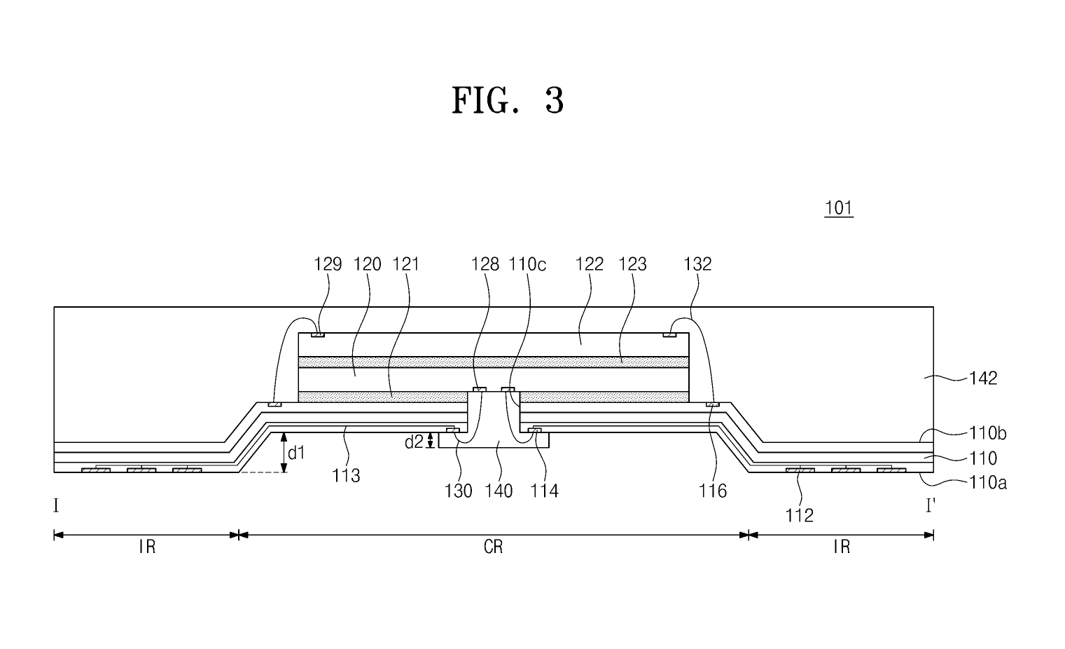

FIG. 3 is a cross-sectional view of a semiconductor package according to a second exemplary embodiment. The cross-sectional view is taken along line I-I′ of FIG. 1. Hereinafter, a semiconductor package according to the second exemplary embodiment will be described with reference to FIGS. 1 and 3. For conciseness of explanation, description about the substantially same elements as those of the first exemplary embodiment described above is omitted.

Referring to FIGS. 1 and 3, a semiconductor package 101 may further include a second semiconductor chip 122 and second bonding wires 132 as well as the elements included in the first exemplary embodiment. The package substrate 110 may further include second bonding pads 116 on the second surface 110b.

The second semiconductor chip 122 may be disposed on the first semiconductor chip 120. The second semiconductor chip 122 may be attached on an upper surface of the first semiconductor chip 120 through an adhesive film 123. The second semiconductor chip 122 may include edge pads 129. The edge pads 129 may be disposed on an edge region of an upper surface of the second semiconductor chip 122. The second semiconductor chip 122 may be, for example, a memory device.

The second bonding wires 132 may electrically connect the second bonding pads 116 of the package substrate 110 and the edge pads 129 of the second semiconductor chip 122. The second bonding wires 132 may be covered by the second molding film 142. The second bolding pads 116 may be electrically connected to the inner interconnection layer 113 through electrodes penetrating the package substrate 110.

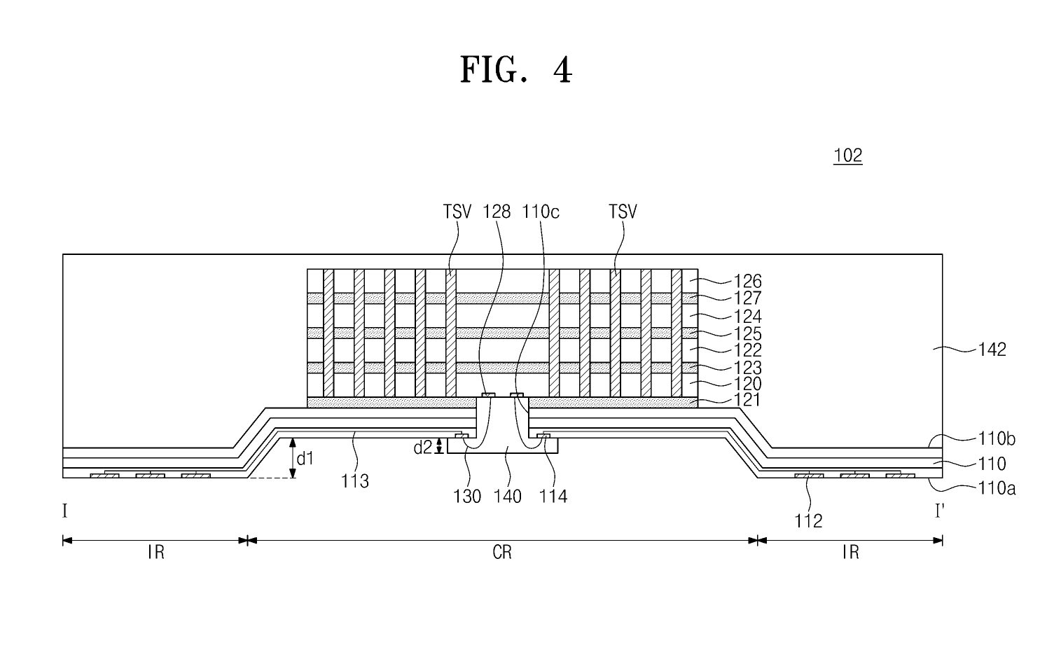

FIG. 4 is a cross-sectional view of a semiconductor package according to a third exemplary embodiment. The cross-sectional view of FIG. 4 is taken along line I-I′ of FIG. 1. Hereinafter, a semiconductor package according to the third exemplary embodiment will be described with reference to FIGS. 1 and 4. For conciseness of explanation, description about the substantially same elements as those of the first exemplary embodiment described above is omitted.

Referring to FIGS. 1 and 4, a semiconductor package 102 may further include a second semiconductor chip 122, a third semiconductor chip 124, a fourth semiconductor chip 126, and penetration electrodes TSV as well as the elements included in the first exemplary embodiment.

The second to fourth semiconductor chips 122, 124 and 126 may be sequentially stacked on the first semiconductor chip 120. The second to fourth semiconductor chips 122, 124 and 126 may be attached through second to fourth adhesive films 123, 125 and 127, respectively. The second to fourth semiconductor chips 122, 124 and 126 may be, for example, memory devices.

The penetration electrodes TSV may be disposed to penetrate the first to fourth semiconductor chips 120, 122, 124 and 126. The penetration electrodes TSV may electrically connect the first to fourth semiconductor chips 120, 122, 124 and 126.

The semiconductor package 102 having four semiconductor chips 120, 122, 124 and 126 according to the third exemplary embodiment has been described with reference to FIGS. 1 and 4. However, it will be also possible to apply a structure in which two, three or five or more semiconductor chips are stacked in the same manner as the above case. That is, four semiconductor chips are described; however, the number is not particularly limited, and one of ordinary skill in the art will understand how to add more or fewer semiconductor chips based on the above description of the third exemplary embodiment.

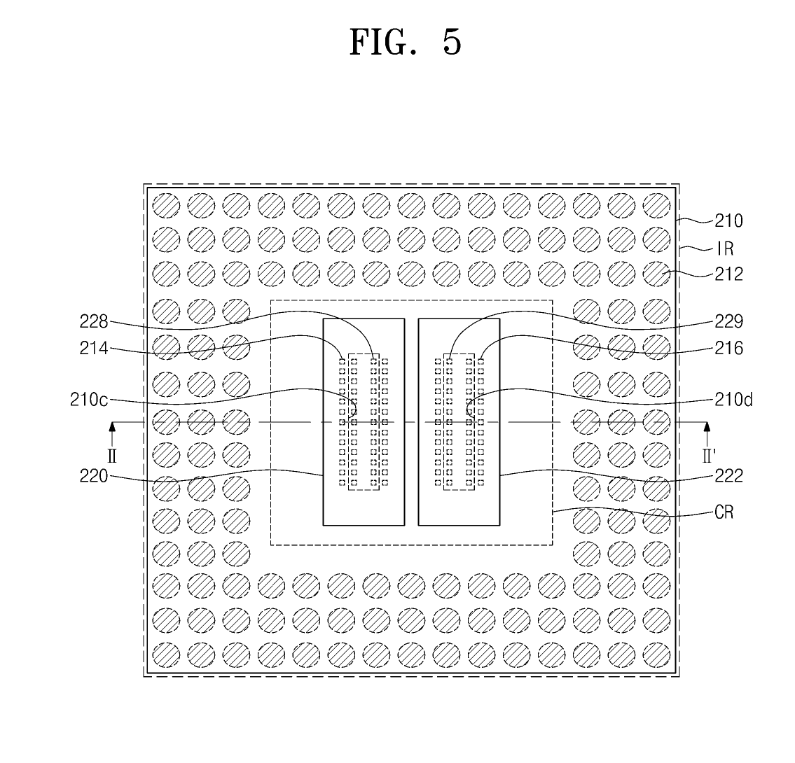

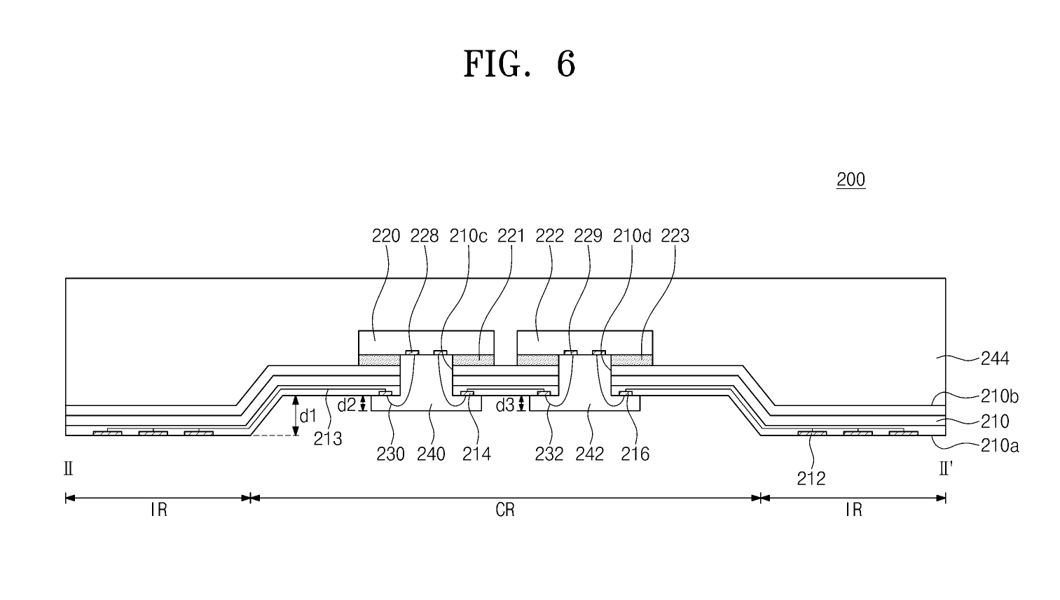

FIG. 5 is a plane view of a semiconductor package according to a fourth exemplary embodiment. FIG. 6 is a cross-sectional view taken along line II-IF of FIG. 5. Hereinafter, a semiconductor package according to the fourth exemplary embodiment will be described with reference to FIGS. 5 and 6.

Referring to FIGS. 5 and 6, a semiconductor package 200 may include a package substrate 210, a first semiconductor chip 220, a second semiconductor chip 222, first bonding wires 230, second bonding wires 232, a first molding film 240, a second molding film 242, and a third molding film 244.

The package substrate 210 may have a first surface 210a and a second surface 210b opposed to the first surface 210a, and may include a chip region CR at a center thereof and an interconnection region IR around the chip region CR. The first surface 210a of the package substrate 210 may have a recessed portion in the chip region CR and the second surface 210b of the package substrate 210 may have a protruding portion in the chip region CR, the protruding portion corresponding to the recessed portion. According to this exemplary embodiment, the package substrate 210 may have a first opening 210c and a second opening 210d formed in the chip region CR and extending from the first surface 210a to the second surface 210b. The first opening 210c and the second opening 210d may be spaced apart from each other. The package substrate 210 may include connection pads 212, first bonding pads 214, and second bonding pads 216. The connection pads 212 may be disposed on the first surface 210a of the interconnection region IR, the first bonding pads 214 may be disposed adjacent to the first opening 210c on the first surface 210a of the chip region CR, and the second bonding pads 216 may be disposed adjacent to the second opening 210d on the first surface 210a of the chip region CR. The first bonding pads 214 and the second bonding pads 216 may be electrically connected to the connection pads 212 through the inner interconnection layer 213. The connection pads 212, the first bonding pads 214, the second bonding pads 216 and the inner interconnection layer 213 may be formed on the same layer. The some exemplary embodiments, the package substrate 210 may include a plurality of stacked insulation layers, and the connection pads 212, the first bonding pads 214, the second bonding pads 216 and the inner interconnection layer 213 may be disposed between the stacked insulation layers. The connection pads 212, the first bonding pads 214 and the second bonding pads 216 may be exposed by an opening formed on the insulation layer. For example, the package substrate 210 may be a printed circuit board or a flexible printed circuit board.

The first semiconductor chip 220 may be disposed on the second surface 210b of the package substrate 210 so as to cover the first opening 210c. In case that the second surface 110b of the package substrate 210 has the protruding portion, the first semiconductor chip 220 may be disposed on the protruding portion of the second surface 210b. The first semiconductor chip 220 may be attached to the second surface 210b of the package substrate 210 using a first adhesive film 221. The first semiconductor chip 220 may include first center pads 228. The first center pads 228 may be disposed on a lower surface of the first semiconductor chip 220 exposed through the first opening 210c. The first semiconductor chip 220 may be, for example, a memory device, such as, for example, a DRAM, NAND flash, NOR flash, OneNAND, PRAM or MRAM, or the like.

The second semiconductor chip 222 may be disposed on the second surface 210b of the package substrate 210 so as to cover the second opening 210d. In case that the second surface 210b of the package substrate 210 has the protruding portion, the second semiconductor chip 222 may be disposed on the protruding portion of the second surface 210b. The second semiconductor chip 222 may be attached to the second surface 210b of the package substrate 210 using a second adhesive film 223. The second semiconductor chip 222 may include second center pads 229. The second center pads 229 may be disposed on a lower surface of the second semiconductor chip 222 exposed through the second opening 210d. The second semiconductor chip 222 may be, for example, a memory device, such as, for example, a DRAM, NAND flash, NOR flash, OneNAND, PRAM or MRAM, or the like. The first semiconductor chip 220 and the second semiconductor chip 222 may be arranged in parallel to each other on the same level. That is, the first semiconductor chip 220 and the second semiconductor chip 222 may be arranged side by side on the second surface 210b.

The first bonding wires 230 may be provided to penetrate the first opening 210c. The first bonding wires 230 may electrically connect the first bonding pads 214 of the package substrate 210 and the first center pads 228 of the first semiconductor chip 220.

The second bonding wires 232 may be provided to penetrate the second opening 210d. The second bonding wires 232 may electrically connect the second bonding pads 216 of the package substrate 210 and the second center pads 229 of the second semiconductor chip 222.

The first molding film 240 may be formed so as to cover the first bonding pads 214, the first center pads 228 and the first bonding wires 230. The first molding film 240 may fill the first opening 210c of the package substrate 210. A recessed depth d1 of the recessed portion of the package substrate 210 may be more than a distance d2 between the first surface 210a of the recessed portion and a lowermost surface of the first molding film 240.

The second molding film 242 may be formed so as to cover the second bonding pads 216, the second center pads 229 and the second bonding wires 232. The second molding film 242 may fill the second opening 210d of the package substrate 210. The recessed depth d1 of the recessed portion of the first surface 210a may be more than a distance d3 between the recessed portion of the first surface 210a and a lowermost surface of the second molding film 242.

The third molding film 244 may be formed so as to cover the first semiconductor chip 220, the second semiconductor chip 222 and the second surface 210b of the package substrate 210. The third molding film 244 may cover the first semiconductor chip 220, the second semiconductor chip 222, and all or a portion of the second surface 110b. The first, second and third molding films 240, 242 and 244 may include an epoxy molding compound.

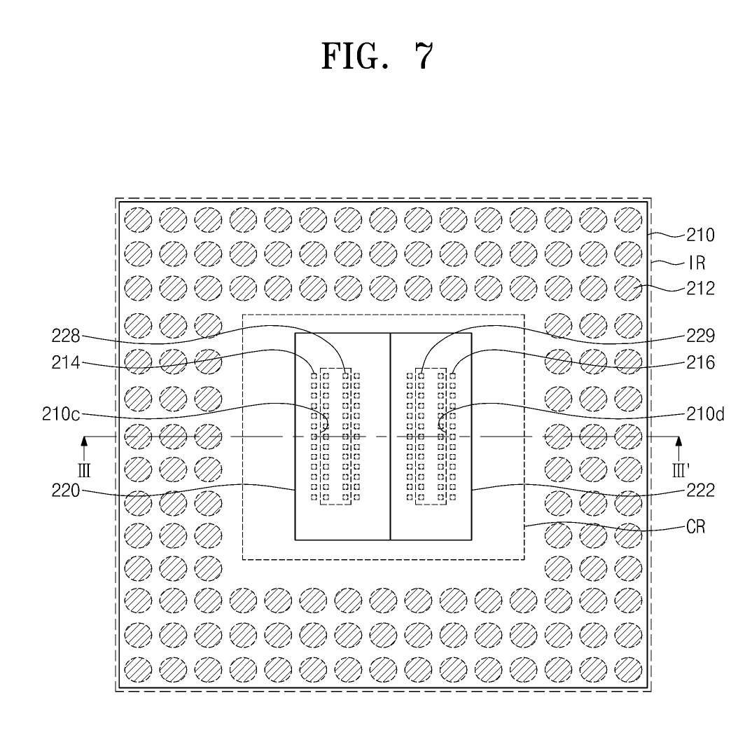

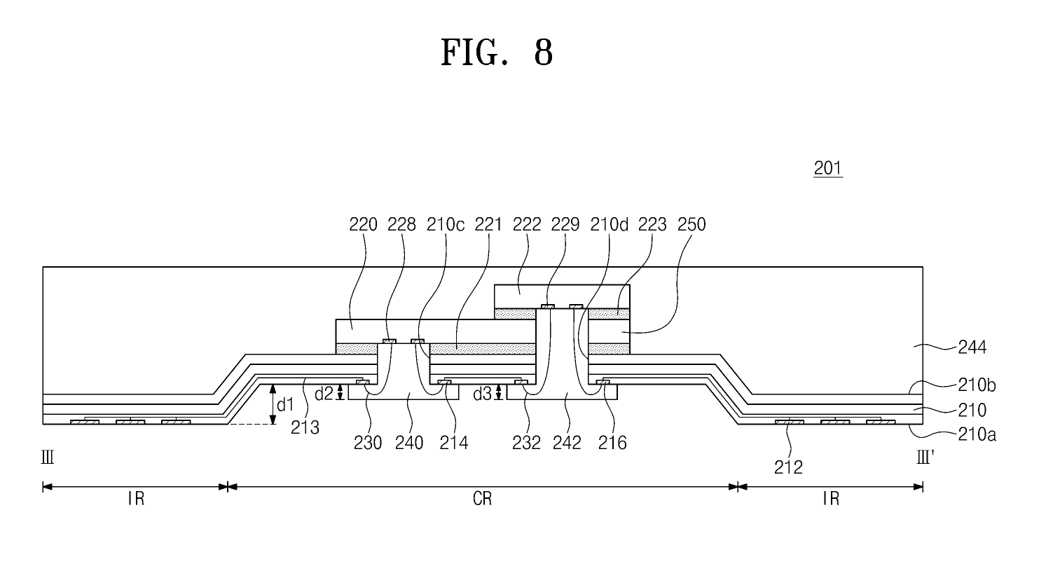

FIG. 7 is a plane view of a semiconductor package according to a fifth exemplary embodiment. FIG. 8 is a cross-sectional view taken along line III-III′ of FIG. 7. Hereinafter, a semiconductor package according to the fifth exemplary embodiment will be described with reference to FIGS. 7 and 8. For conciseness of explanation, description about the substantially same elements as those of the fourth exemplary embodiment described above is omitted.

Referring to FIGS. 7 and 8, a semiconductor package 201 may further include a spacer 250 as well as the elements included in the fourth exemplary embodiment.

The spacer 250 may be disposed on a second surface 210b of a package substrate 210. A second opening 210d may be exposed between the first semiconductor chip 220 and the spacer 250. That is, in FIG. 8, for example, a leftmost edge of the spacer 250 and a rightmost edge of the first semiconductor chip 220 may define the second opening 210d. The spacer 250 may have the same height as that of the first semiconductor chip 220 including a first adhesive film 221.

The first semiconductor chip 220 may extend to be adjacent to the second opening 210d. A second semiconductor chip 222 may be disposed on a portion of the extended first semiconductor chip 220 and at least a portion of the spacer 250 to cover the second opening 210d. The second semiconductor chip 222 may be attached to the first semiconductor chip 220 and the spacer 250 using a second adhesive film 223. Second center pads 229 of the second semiconductor chip 222 may be exposed through the second opening 210d between the first semiconductor chip 220 and the spacer 250.

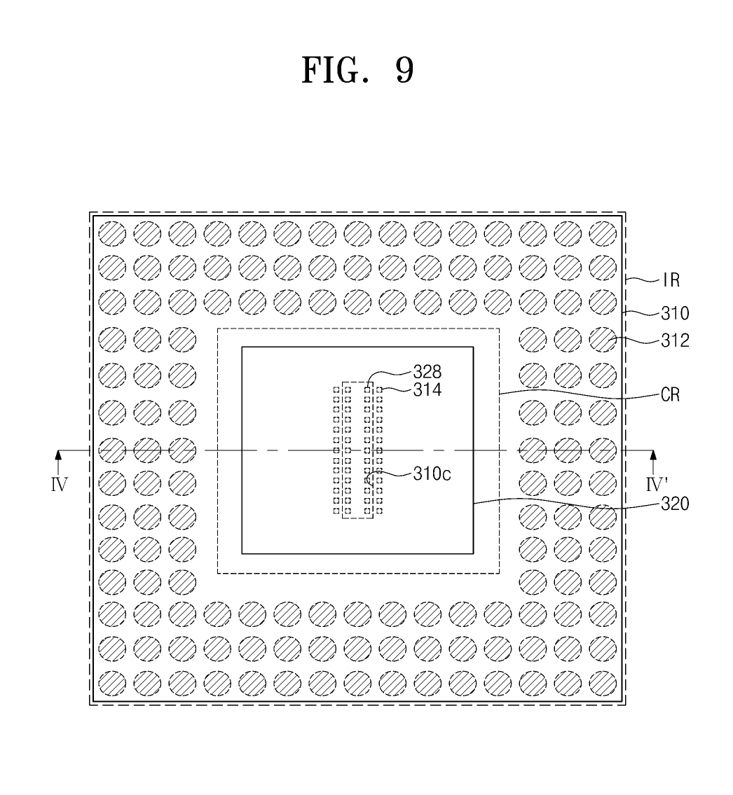

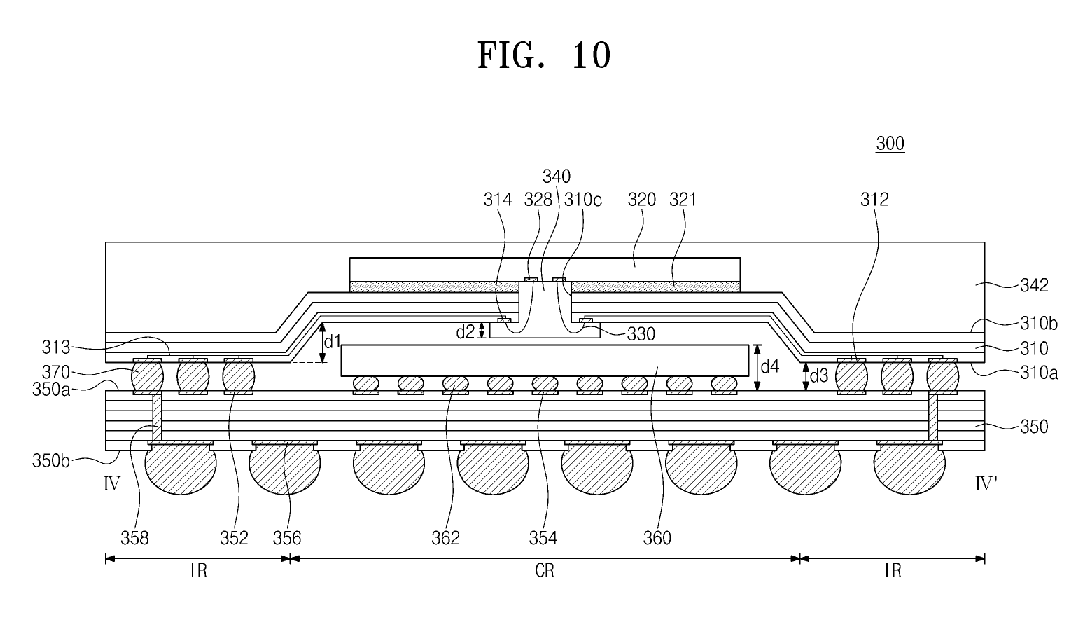

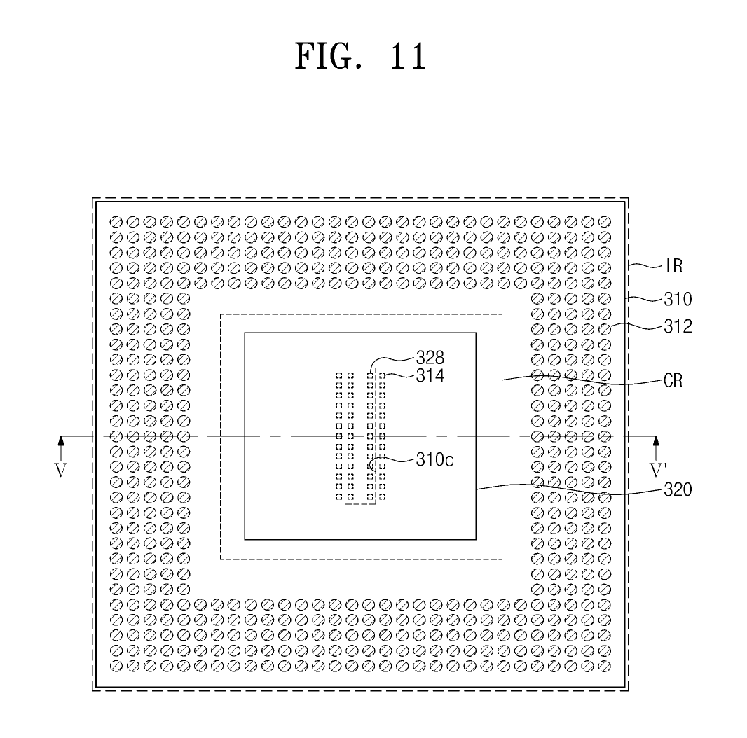

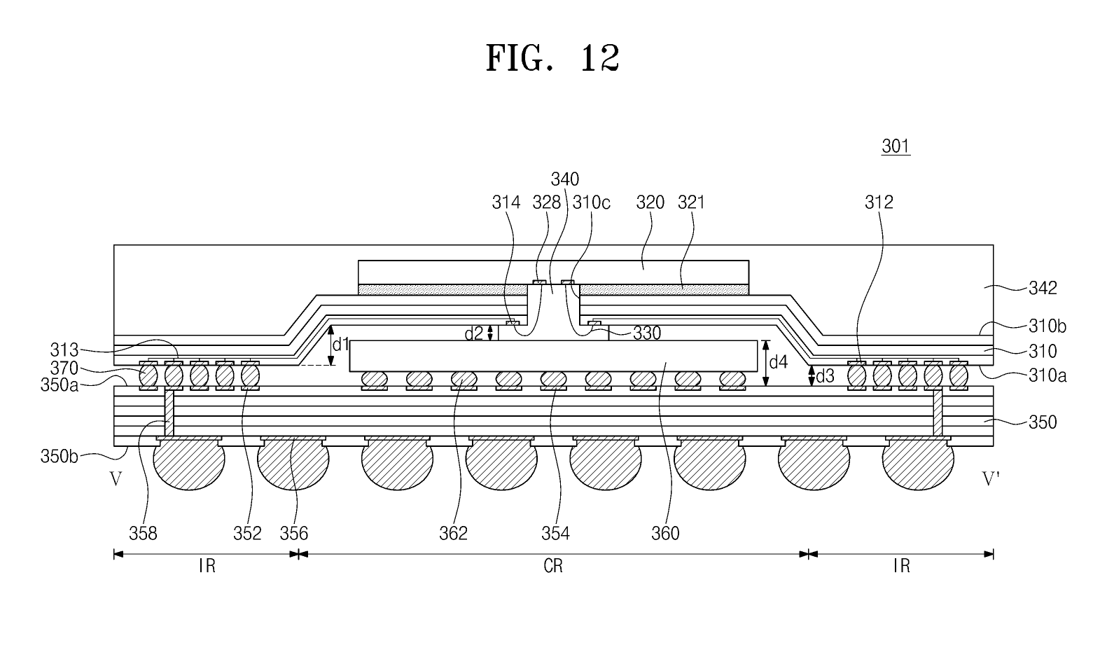

FIGS. 9 and 11 are plane views of stack type semiconductor packages according to respective exemplary embodiments. FIGS. 10 and 12 are cross-sectional views taken along line IV-IV′ of FIG. 9 and line V-V′ of FIG. 11, respectively. Hereinafter, stack type semiconductor packages according to exemplary embodiments will be described with reference to FIGS. 9 to 12.

Referring to FIGS. 9 to 12, each of semiconductor packages 300 and 301 may include an upper package substrate 310, an upper semiconductor chip 320, bonding wires 330, a first molding film 340, a second molding film 342, a lower package substrate 350, a lower semiconductor chip 360, and connection members 370.

The upper package substrate 310 may have a first surface 310a and a second surface 310b opposed to the first surface 310a, and may include a chip region CR at a center thereof and an interconnection region IR around the chip region CR. The first surface 310a of the upper package substrate 310 may have a recessed portion in the chip region CR and the second surface 310b may have a protruding portion in the chip region CR, the protruding portion corresponding to the recessed portion. Also, the upper package substrate 310 may have an opening 310c formed in the chip region CR and extending from the first surface 310a to the second surface 310b. The upper package substrate 310 may include upper connection pads 312 and first bonding pads 314. The upper connection pads 312 may be disposed on the first surface 310a of the interconnection region IR and the first bonding pads 314 may be disposed adjacent to the opening 310c on the first surface 310a of the chip region CR. The upper connection pads 312 and the first bonding pads 314 may be electrically connected to each other through an inner interconnection layer 313. The upper connection pads 312, the first bonding pads 314 and the inner interconnection layer 313 may be formed on the same layer. In some exemplary embodiments, the upper package substrate 310 may include a plurality of stacked insulation layers, and the upper connection pads 312, the first bonding pads 314 and the inner interconnection layer 313 may be disposed between the stacked insulation layers. The upper connection pads 312 and the first bonding pads 314 may be exposed by an opening formed on the insulation layer. For example, the upper package substrate 310 may be a printed circuit board or a flexible printed circuit board.

The upper semiconductor chip 320 may be disposed on the second surface 310b of the upper package substrate 310 so as to cover the opening 310c. In case that the second surface 310b of the upper package substrate 310 has a protruding portion, the upper semiconductor chip 320 may be disposed on the protruding portion of the second surface 310b. The semiconductor chip 320 may be attached to the second surface 310b of the upper package substrate 310 using an adhesive film 321. The upper semiconductor chip 320 may include center pads 328. The center pads 328 may be disposed on a lower surface of the upper semiconductor chip 320 exposed through the opening 310c of the upper package substrate 310. The upper semiconductor chip 320 may be, for example, a memory device, such as, for example, a DRAM, NAND flash, NOR flash, OneNAND, PRAM or MRAM, or the like.

The bonding wires 330 may be provided to penetrate the opening 310c. The bonding wires 330 may electrically connect the first bonding pads 314 of the upper package substrate 310 and the center pads 328 of the upper semiconductor chip 320.

The first molding film 340 may be formed so as to cover the first bonding pads 314, the center pads 328 and the bonding wires 330. The first molding film 340 may fill the opening 310c. A recessed depth d1 of the recessed portion of the upper package substrate 310 may be more than a distance d2 between the recessed portion of the first surface 310a and a lowermost surface of the first molding film 340.

The second molding film 342 may be formed so as to cover the upper semiconductor chip 320 and the second surface 310b of the upper package substrate 310. The second molding film 342 may cover the upper semiconductor chip 320 and all or a portion of the second surface 310b. The first molding film 340 and the second molding film 342 may include an epoxy molding compound.

The lower package substrate 350 is disposed under the upper package substrate 310. The lower package substrate 350 may include lower connection pads 352, second bonding pads 354, outer connection pads 356, and inner interconnection lines 358. The lower connection pads 352 may be disposed on an upper surface of the lower package substrate 350 so as to face the upper connection pads 312. The second bonding pads 354 may be disposed on an upper surface of the lower package substrate 350 and the outer connection pads 356 may be disposed on a lower surface of the lower package substrate 350. The lower connection pads 352 and the second bonding pads 354 may be electrically connected to each other through an interconnection layer in the lower package substrate 350. The inner interconnection lines 358 may penetrate the lower package substrate 350 to electrically connect the upper connection pads to the outer connection pads 356.

The lower semiconductor chip 360 may be disposed between the upper package substrate 310 and the lower package substrate 350. At least a portion of the lower semiconductor chip 360 may be inserted into the recessed portion of the upper package substrate 310. The lower semiconductor chip 360 may be electrically connected to the second bonding pads 354. As an example, the lower semiconductor chip 360 may be electrically connected to the second bonding pads 354 through bumps 362 disposed on the second bonding pads 354. The lower semiconductor chip 360 may be, for example, a system on a chip (SOC). Meanwhile, according to the exemplary embodiment shown in FIGS. 9 and 10, an upper surface of the lower semiconductor chip 360 may be spaced apart from the first molding film 340. On the other hand, according to the exemplary embodiment shown in FIGS. 11 and 12, an upper surface of the lower semiconductor chip 360 may contact the first molding film 340.

The connection members 370 may be disposed between the upper connection pads 312 and the lower connection pads 352 to electrically connect the upper connection pads 312 and the lower connection pads 352 to each other. A height d3 of the connection members 370 may be less than a distance d4 between an upper surface of the lower package substrate 350 and the upper surface of the lower semiconductor chip 360. Thus, the height d3 of the connection members 370 may be decreased, and an area occupied by each of the connection members 370, an area of each of the upper connection pads 312 and an area of each of the lower connection pads may be decreased. Also, a spacing between the connection members 370, a spacing between the connection pads 312, and a spacing between the lower connection pads 352 may be narrowed. As a result, the size of the stack type semiconductor package may be further decreased. Also, the numbers of the connection members 370, the upper connection pads 312 and the lower connection pads 352 electrically connecting the upper semiconductor package and the lower semiconductor package may be increased, so that a more highly integrated stack type semiconductor package may be provided.

While the exemplary embodiments for the stack type semiconductor packages shown in FIGS. 9 to 12 show and describe that the upper semiconductor package is a semiconductor package according to the first exemplary embodiment, the inventive concept is not limited thereto, and it should be understood that other exemplary embodiments in which the semiconductor packages according to the second to fifth exemplary embodiments become upper semiconductor packages are also included in the scope of the inventive concept.

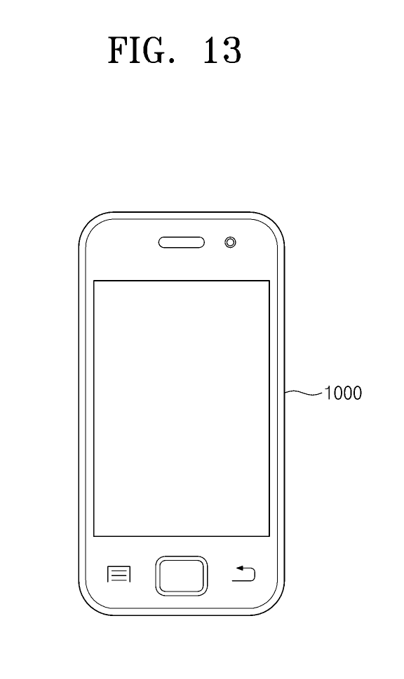

FIG. 13 is a view illustrating an electronic device to which a semiconductor package according to an exemplary embodiment may be applied.

FIG. 13 is a view illustrating a mobile phone 1000 to which a semiconductor package according to an exemplary embodiment may be applied. As another example, the semiconductor package according to exemplary embodiments may be applied to a smart phone, a personal digital assistant (PDA), a portable multimedia player (PMP), a digital multimedia broadcast (DMB) device, a global positioning system (GPS) device, a handheld gaming console, a portable computer, a web tablet, a wireless phone, a digital music player, a memory card, or any other devices that transmit and/or receive information in a wireless environment.

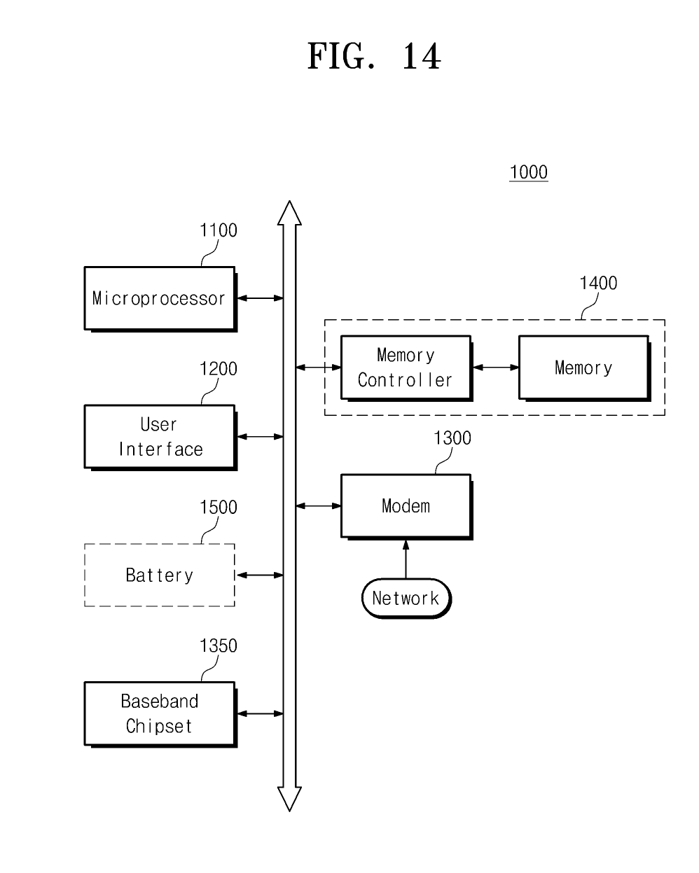

FIG. 14 is a block diagram schematically illustrating an electronic device to which a semiconductor package according to an exemplary embodiment may be applied.

Referring to FIG. 14, an electronic device 1000 according to an exemplary embodiment includes a microprocessor 1100, a user interface 1200, a modem 1300 such as a baseband chipset 1350, and a semiconductor package 1400 according to the exemplary embodiments described above.

When the electronic device is a mobile device, a battery 1500 for providing an operation voltage of the electronic device may be additionally provided. Furthermore, it will be understood by those skilled in the art that the electronic device according to the inventive concept may further include an application chipset, a camera image processor (CIS), etc.

According to semiconductor packages according to exemplary embodiments described above, bonding wires may directly connect a semiconductor chip and bonding pads formed on a lower surface of a package substrate through an opening of the package substrate. Thus, the package substrate is formed with a single interconnection layer, and is thereby capable of reducing the manufacturing costs of the semiconductor package.

According to semiconductor packages according to exemplary embodiments described above, a spacing between an upper package substrate and a lower package substrate may be decreased. Thus, the size of and the distance between connection members connecting the upper package and the lower package may be decreased. Accordingly, the size of the semiconductor package may be further decreased.

Although exemplary embodiments are described above with reference to the accompanying drawings, those skilled in the art will understand that the present inventive concept may be implemented in various ways without changing the necessary features or the spirit of the present disclosure. Thus, the above embodiments should be construed to be exemplary rather than as limitative.

What is claimed is:

1. A semiconductor package comprising:
a package substrate comprises a first surface having a recessed portion, a second surface opposed to the first surface, a first opening extending from the recessed portion of the first surface to the second surface, and first bonding pads provided on the first surface;
a first semiconductor chip disposed on the second surface of the package substrate to cover the first opening and comprising first center pads exposed through the first opening;
first bonding wires electrically connecting the first center pads and the first bonding pads through the first opening; and
a first molding film covering the first bonding pads, the first center pads, and the first bonding wires,
wherein a depth of the recessed portion is greater than a distance between the recessed portion of the first surface and a lowermost surface of the first molding film.

2. The semiconductor package of claim 1, wherein the second surface has a protruding portion corresponding to the recessed portion and the first semiconductor chip is disposed on the protruding portion.

3. The semiconductor package of claim 1, wherein the package substrate has a chip region at a center thereof and an interconnection region around the chip region, and the package substrate further comprises connection pads provided on the first surface in the interconnection region.

4. The semiconductor package of claim 3, wherein the package substrate further comprises an inner interconnection layer electrically connecting the first bonding pads and the connection pads, and the inner interconnection layer, the first bonding pads and the connection pads are formed on a same layer.

5. The semiconductor package of claim 1, further comprising:
a second semiconductor chip disposed on the first semiconductor chip and comprising edge pads;
second bonding pads disposed on the second surface of the package substrate; and
second bonding wires electrically connecting the edge pads and the second bonding pads.

6. The semiconductor package of claim 1, further comprising:
a second semiconductor chip disposed on the first semiconductor chip; and
penetration electrodes penetrating the first semiconductor chip and the second semiconductor chip,
wherein the first semiconductor chip and the second semiconductor chip are electrically connected through the penetration electrodes.

7. The semiconductor package of claim 1, wherein the package substrate further comprises second bonding pads provided on the first surface, and a second opening extending from the first surface to the second surface in the recessed portion, the second opening being spaced apart from the first opening, and
the semiconductor package further comprising:
a second semiconductor chip disposed on the second surface of the package substrate to cover the second opening, the second semiconductor having second center pads on a surface thereof exposed through the second opening;
second bonding wires electrically connecting the second center pads and the second bonding pads through the second opening; and
a second molding film covering the second bonding pads, the second center pads, and the second bonding wires.

8. The semiconductor package of claim 7, further comprising a spacer disposed on the second surface of the package substrate, wherein the second opening is defined by an edge of the first semiconductor chip and an edge of the spacer, and the second semiconductor chip is disposed on the first semiconductor chip and the spacer.

9. A stack type semiconductor package comprising:
an upper package substrate comprising a first surface having a recessed portion, a second surface opposed to the first surface, an opening extending from the recessed portion of the first surface to the second surface, first bonding pads provided on the first surface, and upper connection pads provided on the first surface;
an upper semiconductor chip disposed on the second surface of the upper package substrate to cover the opening and comprising center pads exposed through the opening;
bonding wires electrically connecting the center pads and the bonding pads through the opening;
a molding film covering the bonding pads, the center pads, and the bonding wires;
a lower package substrate disposed under the upper package substrate and comprising an upper surface and lower connection pads provided on the upper surface;
a lower semiconductor chip disposed between the upper package substrate and the lower package substrate and electrically connected to the lower package substrate; and
connection members electrically connecting the upper connection pads and the lower connection pads,
wherein at least a portion of the lower semiconductor chip is inserted into the recessed portion.

10. The stack type semiconductor package of claim 9, wherein a depth of the recessed portion is greater than a distance between the recessed portion of the first surface the recessed portion and a lowermost surface of the molding film.

11. The stack type semiconductor package of claim 9, wherein a height of the connection members is less than a distance between the upper surface of the lower package substrate to an upper surface of the lower semiconductor chip.

12. The stack type semiconductor package of claim 9, wherein an upper surface of the lower semiconductor chip and a lower surface of the molding film are in contact with each other.

13. The stack type semiconductor package of claim 9, wherein the upper package substrate further comprises an inner interconnection layer electrically connecting the bonding pads and the upper connection pads, and the inner interconnection layer, the bonding pads and the upper connection pads are formed on the same layer.

14. The stack type semiconductor package of claim 9, wherein the upper package substrate has a chip region at a center thereof and an interconnection region around the chip region, and the upper connection pads are provided in the interconnection region.

15. The stack type semiconductor package of claim 14, wherein the lower connection pads face the upper connection pads, and the connection members electrically connect pairs of the upper connection pads and the lower connection pads facing each other, respectively.

16. A stack type semiconductor package comprising:
a first substrate comprising bonding pads, a recessed portion, and an opening formed in the recessed portion;
a first semiconductor chip disposed on the first substrate and covering the opening, the first semiconductor chip comprising center pads exposed through the opening;
bonding wires extending through the opening and connecting the center pads of the first semiconductor chip and the bonding pads of the first substrate;
a molding film disposed on a surface of the first substrate opposite from the first semiconductor chip and covering the opening, the bonding pads, the center pads, and the bonding wires;
a second substrate; and
a second semiconductor chip disposed on the second substrate, the second semiconductor chip being disposed between the first substrate and the second substrate, wherein at least a portion of the second semiconductor chip is inserted into the recessed portion of the first substrate.

17. The stack type semiconductor package of claim 16, wherein the molding film does not contact the second semiconductor chip.

18. The stack type semiconductor package of claim 16, wherein the molding film contacts the second semiconductor chip.

19. The stack type semiconductor package of claim 16, wherein:
the first substrate further comprises first connection pads,
the second substrate further comprises second connection pads,
the stack type semiconductor package further comprises connection members electrically connecting the first connection pads and the second connection pads, and
a height of the connection members is less than a distance from a surface of the second substrate on which the second semiconductor chip is disposed to a surface of the second semiconductor chip that is inserted into the recessed portion.

20. The stack type semiconductor package of claim 16, wherein the bonding pads are provided on the first substrate in the recessed portion.
